(19) United States
(12) Patent Application Publication
(10) Pub. No.: US 2021/0305780 A1
(43) Pub. Date: Sep. 30, 2021

(54) HIGH-POWER HIGH-BEAM-QUALITY LASER DIODE SYSTEMS USING COUPLED LARGE LASER CORES

(71) Applicant: Mieng Pai, Bellingham, WA (US)

(72) Inventor: Mieng Pai, Bellingham, WA (US)

(21) Appl. No.: 16/830,263

(22) Filed: Mar. 25, 2020

(51) Int. Cl. H01S 5/14; H01S 5/40

(52) U.S. Cl. CPC H01S 5/141; H01S 5/4025

(57) ABSTRACT

System and method for utilizing a serial array (10) of large laser cores (11), positioned inside an external cavity formed with full reflection mirrors (12) and a partial reflection mirror (13), containing a mode-selection mechanism, based on a seeding laser (14), a Fabry-Perot (16), and an isolator (15), for ensuring only the axial wave (17) can exist, generating correspondingly an output beam (18) of high power as well high beam quality.

### CROSS REFERENCE TO RELATED APPLICATIONS

The present application claims priority from and benefit of U.S. Provisional Patent Application No. 62/823,066 filed on Mar. 25, 2019 and titled “A Large-Core, Vertical-Cavity Coherent-Array-Laser (LC-VCCAL) Method”. The disclosure of the above-identified provisional patent application is incorporated herein by reference.

### FIELD OF THE INVENTION

This invention relates to laser diode systems, particularly it relates to laser diode systems of high power as well as high beam quality.

### BACKGROUND OF THE INVENTION

Standard high power laser diodes are in terms of either diode bar/stack arrays (edge emitting devices), or VCSEL arrays (surface emitting devices). These systems offer high power (tens to hundred of watts), but suffer from a deteriorating beam quality as power increases.

In both cases (diode bars/stacks, VCSEL arrays), the approach to high power is by increasing the number of emitters. In diode bars/stacks, emitters are lined up inside a chip. A chip is broken off to several bars. Each bar consists of a row of emitters (like the teeth of a comb). Light comes out of a bar's edge. Multiple bars are piled up on top of each other to form a stack. In VCSEL, a chip consists of a plane of emitters (each a thin vertical cylinder, chip thickness, circular in cross section). Light comes out of the chip surface.

In both cases (diode bars/stacks, VCSEL arrays), while each emitter is low in power, thousands (or tens of thousands) of emitters as a whole can bring power into hundreds of watt. However, in these systems, the emitters are independent light sources, not coherent with each other. The beam quality goes down as the number of emitters increases towards high power.

This invention describes an approach that aims towards high power as well as coherence. It seeks a large gain volume (for high power) by using a large core for each emitter and by using many emitters. The core of an emitter refers to the active region where the optical gain occurs. A large gain volume is needed for high power. Further, it ensures coherence by coupling these emitter cores as a coherent serial array (i.e. train like). The result is a single lasing wave for all cores. In this way, power can be increased by adding cores (into the array) without deterioration of beam quality.

### SUMMARY OF THE INVENTION

The cores are circular cylinders like in VCSEL. Now, however, one chip supports only one core (as oppose to thousands of cores per chip in VCSEL). Core diameters are large, hundreds of microns (as opposed to microns in VCSEL). The core chips are flipped up to be vertically standing and then lined up to form a serial array (a chip holder is needed for the purpose). The array is placed inside an external cavity. The cavity contains a mode-selection mechanism that deals with multi-mode excitations which destroy beam quality. The mode selection ensures a single lasing wave for the whole array. Each core chip is attached to a large surface for heat dissipation into air. The result is (1) a large gain volume for high power (many cores, each core a large gain volume), (2) a single lasing wave for high beam quality, and (3) an air-cooled system.

### BRIEF DESCRIPTION OF THE DRAWINGS

FIG. 1 is a schematic diagram of the set up in accordance with the invention.

FIG. 2 is a depiction of wafer, chip, and chip-package.

FIG. 3 is a depiction of VCSEL cell structure.

FIG. 4 is a depiction of the current core structure

FIG. 5 is a depiction of multi mode problems in a large core

FIG. 6 is a depiction of mode selection by FP

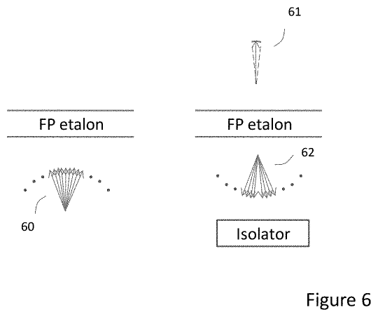

FIG. 7 is a depiction of heat removal by chip package

### DETAILED DESCRIPTION OF THE INVENTION

### System Description

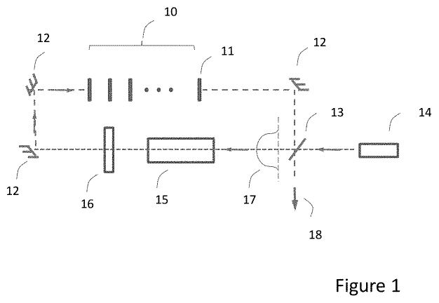

FIG. 1 shows the system set up. A serial array 10 of laser cores 11 is positioned inside an external cavity formed with full reflection mirrors 12 and partial reflection mirror 13. The cavity contains a mode-selection mechanism, based on a seeding laser 14, a Fabry-Perot (FP) 16, and an isolator 15. The mechanism ensures that only the axial wave 17 can exist inside the cavity. The axial lasing wave 17 is a quasi-plane wave (a plane wave with a spatial extent that is finite but large relative to wavelength). The corresponding output beam 18 has a high beam quality.

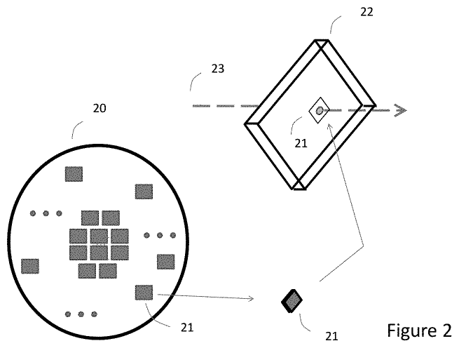

FIG. 2 shows laser core chips and packages. A chip 21 is taken from a wafer 20 and then attached (with good thermal contact) to a package 22 for heat removal. The packages 22, each with a chip at the center, are then lined up forming an array. The array is held in place using a holder that centers chips along the array axis 23.

### Chip Structure

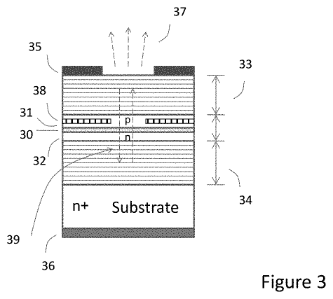

The chip structure is similar to that of a VCSEL chip (with a few modifications). As shown in FIG. 3, a VCSEL chip contains a MQW active region 30, sandwiched between a p-region 31 and a n-region 32. It is bordered by DBR gratings on top 33 and at bottom 34 for reflection. A positive electrode 35 on top feeds current towards the negative electrode at the bottom 36. The top electrode 35 has an opening allowing for an output beam 37. Near the active layer 30, a current blocker 38, with a small opening at the center, directs current through the central part of the active region 30. The opening is small, about a micron or so, corresponding to wavelength, so only an axial wave 39 (the vertical direction is the axial direction) exists in the cavity. The small opening, however, limits the gain volume and thus power.

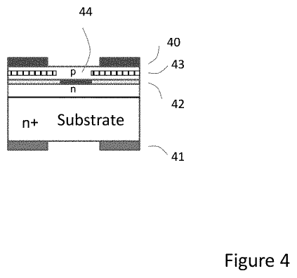

FIG. 4 shows a comparison between our chips with a VCSEL chip. No DBR gratings are needed. The top 40 and bottom electrodes 41 both have openings to let wave through. Near the active region 42, the current blocker 43 remains. But now the opening 44 is much larger, several hundred times of wavelength. For an opening that is 100 times as large as VCSEL, the factor in gain volume is 10\hat{ }4,

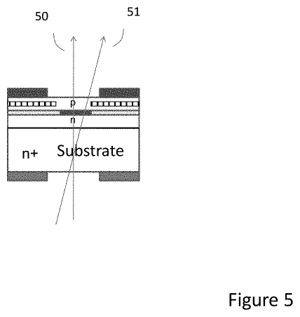

However, as shown in FIG. 5, in addition to the axial waves 50, a large opening gives rise to non-axial waves 51. The non-axial waves are the dreaded multi-modes associated with large cavities (large in the transverse dimension) that destroy beam quality.

### Mode Control and Core Size

The mode control method has been described in a 2016 US patent [1] and paper [2]. The method is summarized here briefly.

As shown in FIG. 5, the FP (Fabry Perot) is a wave direction filter for a fixed frequency given by the seed laser. For a set of input plane waves 60, the FP passes only the portion of plane waves 61 within a sharp direction selection window. Waves outside the direction window are reflected 62 and get absorbed by the isolator. The angular width of the selection window 61 is given by the expression

$$δ = ( {2}^{1 / 2} ) {( \frac{1}{2 MF} + \frac{δω}{{ω}_{o}} )}^{1 / 2}$$

The factor 1/(2MF) is contributed by the FP, where M and F are, respectively, the maximum order and the finesse of the FP. The factor δω/ωₒ is contributed by the seeding laser, where ωₒ is the laser frequency and δω is the frequency width. For reasonable values,

$$M = 1000 \\ F = 100$$

$$\frac{δω}{{ω}_{o}} = \frac{100 MHz}{300 THz} = \frac{1}{3} \times 1 {0}^{- 6}$$

δ is given by.

$$δ = ( {2}^{1 / 2} ) {( \frac{1}{2 M F} + \frac{δω}{{ω}_{o}} )}^{1 / 2} = \frac{1 {0}^{- 2}}{\sqrt{60}}$$

A diffraction-limited Gaussian beam has an angular width given by

$${θ}_{D} = ( \frac{1}{π} ) \frac{λ}{W}$$

where W is the beam width and λ is the wavelength. For our beam to be Gaussian beam like, we need to match δ with θ_{D}, that is

$$δ = {θ}_{D}$$

$$or \\ ( \frac{1}{π} ) ( \frac{λ}{W} ) = \frac{1 {0}^{- 2}}{\sqrt{60}}$$

The condition translates to a ratio between beam size and wavelength given by

$$\frac{W}{λ} \approx 250$$

For a wavelength of 1 micron, the beam size (or core size) can be as large as 250 micron. For a core above that size, multi mode can occur with reduced beam quality. We shall use a ratio 100 (not 250, for safety margin) for estimates.

### Power Estimate

For a core radius of 100 micron, relative to a VCSEL size of 1 micron, the ratio in gain volume is 10\hat{ }4. From that ratio, for a VCSEL power of 1 mW, the power can be scaled up to 10 W. With 100 cores in series, the total power can be scaled up to 1 kilowatt.

### Heat Removal

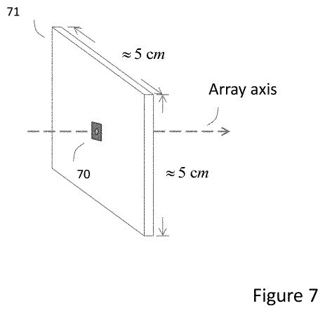

Heat removal becomes more important with increasing power. In this method, each chip provides its own surface for heat removal. Each chip can be connected to a package with a large surface area for heat dissipation. As shown in FIG. 7, a chip (say 5 mm×5 mm) 70 can be attached (with good thermal contact) to a heat-conducting package (say 5 cm×5 cm) 71. Heat flows out from the chip into the package.

Heat removal rate q through forced air flow is given by q=h_{c}A(ΔT), where h_{c} is the convection heat transfer coefficient, A is the surface area, and ΔT is the temperature difference between air and the surface being cooled. The heat transfer coefficient depends on the air flow rate. A reasonable value for moderate air flow rate is h=100 W/m²(° K). Using this value, for a surface area of 5 cm×5 cm×2 (two surfaces), and a temperature difference ΔT=10° K, we obtain a heat removal rate q=5 W.

This simple estimate indicates that air cooling might be sufficient for a power per chip in the 10 W range. If so, then a 100 W system based on 10 chips, or even a 1 kW system based on 100 chips, can be possible with air cooling. This remarkable result is because the heat load per chip remains independent of the number of chips employed in the system.

### Implementation Issues

The design knowledge and fabrication know-how of VCSEL chips can be directly transferred to the current chip. Other components (FP, isolator, feed laser, beam splitters, mirrors, etc) are all standard devices.

1) A problem of

inability of related art to efficiently remove heat from the light-amplifying medium (LAM), which is utilized in a large-core-LAM laser systems configured to generate substantially only the lowest spatial mode at power levels on the order of 1 W or higher,

is solved by

structuring the large-core LAM, for use in a laser system configured to generate substantially only the lowest spatial mode at power levels on the order of 1 W or higher, as group of multiple large-core gain chips disposed coaxially with respect to one another to form a sequence or string of chips separated from one another by appropriate separation distance(s) while, at the same time, equipping each of the constituent LAM chips with an individual heat-sink removal contraption and disposing the so-formed sequence in an external laser cavity that is common to all of the constituent LAM chips.

2) A problem of

inability of related art to efficiently remove heat from the light-amplifying medium (LAM), which is utilized in a large-core-LAM laser systems configured to generate substantially only the lowest spatial mode at power levels on the order of 1 W or higher, while maintaining the spatial quality of such lowest spatial mode output from the laser system

is solved by

fabricating a multiplicity of individual LAM chips, each structured in a layered fashion similar to that of a VCSEL structure having a transverse dimension of the gain medium on the order of 100 microns or larger, but without individual optical reflectors (for example, DBRs) on each of the LAM chips, and forming a compound LAM within the external laser cavity by stringing together the multiplicity of the individual LAM chips disposed on the same axis and spatially-separated from one another such that layers of the layered structures of the individual LAM chips are transverse to the axis, to provide the heat removal from the LAM chips individually and independently from one another.

### REFERENCES

[1] US patent, “Control of spatial mode distribution of a large-core laser diode system”, U.S. Pat. No. 9,385,508, Jul. 5, 2016.
(2) “High power laser diode using a large active core combined with mode control for high beam quality”, D. M. Pai, 2015, High Power Laser Technology and Applications XIII, SPIE Photonics West, Feb. 8-10, 2015, Proceeding of SPIE, Volume 9348, ed. Mark Zediker.

1. A laser system configured to generate first light at an operational wavelength, the laser system comprising:
an optical cavity having an optical axis;
multiple individual light amplifying medium (LAM) chips disposed coaxially with said optical axis inside the optical cavity such that the optical cavity forms an external cavity (EC) with respect to the multiple LAM chips,
wherein said multiple LAM chips are separated from one another along the optical axis;
wherein each of the multiple LAM chips has a corresponding gain region extending by at least 100 microns across the optical axis;
wherein each of the multiple LAM chips is encircled by and in contact with a plate of a heat-transmitting material disposed across the optical axis; and
an optical etalon filter disposed intra-EC across the optical axis.

2. The laser system according to claim 1, wherein said optical etalon filter includes a tunable Fabry-Perot Etalon (FPE) and further comprising a tuner operably connected to said FPE and configured to change an optical length of said FPE.

3. The laser system according to claim 1, wherein the optical cavity is configured as a loop optical cavity with a loop optical path, defined among the constituent reflectors forming the optical cavity, that forms a polygon.

4. The laser system according to claim 1, wherein the optical cavity is configured as a loop optical cavity with a loop optical path, defined among the constituent reflectors forming the optical cavity, that extends in each of three dimensions.

5. The laser system according to claim 1, wherein said optical cavity is formed by at least three reflectors, wherein one or more reflectors of said at least three reflectors is dimensioned to ensure that a first angle is smaller than a second angle,
wherein the first angle being defined as an angle formed between
a cavity line, that connects
(i) a first point defined on a perimeter of a clear aperture of a first reflector of said at least three reflectors with
(ii) a second point on a perimeter of a clear aperture of a second reflector of said at least three reflectors,
and
a portion of the optical axis that connects said first and second reflectors, and
wherein the second angle is determined based on a non-zero angle at which light, that is incident on said optical etalon filter intracavity from the first reflector, constructively interferes with itself upon interaction with the optical etalon such as to propagate towards the second reflector.

6. The laser system according to claim 1, further comprising a seed laser configured outside of the EC to generate a beam of light at the operational wavelength such that, when said beam of light is coupled into the EC, said beam of light propagates through the LD chip along the optical axis.

7. The laser system according to claim 1, wherein each of the individual LAM chips is configured as a multilayer structure with layers transverse to the optical axis

8. claim dependent from 7 and aimed at the structure of the multilayer structure (**details here**) that is devoid of a layer configured as an optical reflector
